(19) United States
(12) Patent Application Publication
(10) Pub. No.: US 2025/0226202 A1
(43) Pub. Date: Jul. 10, 2025

(54) METHOD AND DEVICE FOR ETCHING A SUBSTRATE AND METHOD AND APPARATUS FOR PROCESSING A SUBSTRATE

(71) Applicant: ASM IP Holding B.V., Almere (NL)

(72) Inventors: Rami Khazaka, Leuven (BE); Daner Abdula, Chandler, AZ (US); Yu-Jen Chiu, Tempe, AZ (US)

(21) Appl. No.: 19/007,627

(22) Filed: Jan. 2, 2025

Related U.S. Application Data
(60) Provisional application No. 63/617,575, filed on Jan. 4, 2024.

(51) Int. Cl. H01L 21/02; H01L 21/67

(52) U.S. Cl. CPC H01L 21/02046; H01L 21/67069

(57) ABSTRACT

This disclosure relates to a method and device for etching a substrate as well as a method and apparatus for processing a substrate. The method for etching a substrate comprises providing a substrate comprising a silicon-containing material in a process chamber and etching the silicon-containing material at least partly. The process of etching the silicon-containing material comprises providing a pnictogen-containing gaseous reactant in the process chamber and providing a halogen-containing gaseous reactant in the process chamber. The method for processing a substrate comprises pre-cleaning the substrate to form a cleaned substrate and forming an epitaxial layer on the cleaned substrate.

### CROSS-REFERENCE TO RELATED APPLICATION(S)

This Application claims the benefit of U.S. Provisional Application 63/617,575 filed on Jan. 4, 2024, the entire contents of which are incorporated herein by reference.

### TECHNICAL FIELD

This disclosure generally relates to the fields of microfabrication and nanofabrication. In particular, the present disclosure relates to the field of semiconductor manufacturing technology, for example, the fabrication of integrated circuits.

### BACKGROUND

Semiconductor manufacturing typically involves a sequence of procedures for device fabrication. Each procedure is designed for either depositing material, creating patterns, modifying material, or removing material through processes like etching. As the dimensions of the devices shrink and their designs become increasingly complex, there is a growing need for novel material removal techniques. These techniques should be capable of selectively etching specific materials efficiently, even in the context of intricate device geometries.

### SUMMARY

According to a first aspect, a method for etching a substrate is provided. The method comprises providing the substrate in a process chamber, the substrate comprising a silicon- containing material, and etching the silicon-containing material at least partly. The process of etching the silicon-containing material comprises providing a pnictogen-containing gaseous reactant in the process chamber such that the silicon-containing material is exposed to the pnictogen-containing gaseous reactant to form a modified silicon-containing material. The process of etching the silicon-containing material further comprises providing a halogen- containing gaseous reactant in the process chamber such that the modified silicon-containing material is exposed to the halogen-containing gaseous reactant to at least partly etch the modified silicon-containing material.

According to a second aspect, a method for processing a substrate is provided. The method comprises pre-cleaning the substrate in a process chamber using a method in accordance with the first aspect to form a cleaned substrate and forming an epitaxial layer on the cleaned substrate

According to a third aspect, a device for etching a substrate is provided. The device comprises a process chamber for holding the substrate, a first reactant supply unit for providing a pnictogen-containing gaseous reactant in the process chamber, a second reactant supply unit for providing a halogen-containing gaseous reactant in the process chamber, and a control unit configured to control at least the first reactant supply unit and the second reactant supply unit to conduct a method in accordance with the first aspect.

According to a fourth aspect, an apparatus for processing a substrate is provided. The apparatus comprises a device in accordance with the third aspect for pre-cleaning the substrate to form a cleaned substrate and an epitaxial deposition reactor coupled to the device for transferring the cleaned substrate from the process chamber to the epitaxial deposition reactor without breaking vacuum.

The embodiments discussed below may relate to any of the aspects above, mutatis mutandis.

In some embodiments, the silicon-containing material comprises at least one silicon- oxygen compound, such as silica and/or one or more silicate compounds.

In some embodiments, the silicon-containing material comprises elemental silicon, such as monocrystalline silicon, polycrystalline silicon, and/or amorphous silicon.

In some embodiments, the pnictogen-containing gaseous reactant comprises an inorganic pnictogen species, such as an inorganic pnictogen compound, e.g., a pnictogen chloride or a pnictogen hydride.

In some embodiments, the pnictogen-containing gaseous reactant comprises phosphorus and/or arsenic.

In some embodiments, the halogen-containing gaseous reactant comprises a chlorine-containing species, such as a chlorine-containing compound, e.g., chlorine or carbon tetrachloride.

In some embodiments, etching the silicon-containing material is implemented as a thermal etch process.

In some embodiments, etching the silicon-containing material comprises maintaining temperature of the substrate less than or equal to 600° C., or to 550° C., or to 500° C., or to 450° C. and/or greater than or equal to 50° C., or to 100° C., or to 150° C., or to 200° C., or to 250° C.° C., or to 300° C., or to 350° C.

In some embodiments, etching the silicon-containing material comprises removing excess pnictogen-containing gaseous reactant from the process chamber prior to providing a halogen-containing gaseous reactant and/or removing excess halogen-containing gaseous reactant from the process chamber after providing a halogen-containing gaseous reactant.

In some embodiments, providing a pnictogen-containing gaseous reactant and providing a halogen-containing gaseous reactant at least partly temporally overlap.

In some embodiments, etching the silicon-containing material is implemented as a cyclic etch process.

In some embodiments, etching the silicon-containing material is implemented as a self-limiting etch process.

In some embodiments, a method for etching a substrate is implemented as a semiconductor manufacturing pre-cleaning method.

In some embodiments, pre-cleaning the substrate and forming an epitaxial layer are performed in the process chamber and an epitaxial deposition reactor separate from the process chamber, respectively, and the method for processing a substrate comprises transferring the cleaned substrate from the process chamber to the epitaxial deposition reactor without breaking vacuum.

In some embodiments, both pre-cleaning the substrate and forming an epitaxial layer are performed in the process chamber.

In some embodiments, the device comprises a purge gas supply unit for providing a purge gas in the process chamber.

In some embodiments, the device comprises an epitaxial precursor supply unit for providing one or more precursors in the process chamber.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### DESCRIPTION OF THE DRAWINGS

A more complete understanding of the embodiments of the present disclosure may be derived by referring to the detailed description and claims when considered in connection with the following illustrative figures:

FIG. 1 illustrates a method for etching a substrate,

FIG. 2 shows a method for processing a substrate,

FIG. 3 illustrates a series of stages of a method for processing a substrate,

FIG. 4 depicts a device for etching a substrate,

FIG. 5 shows an apparatus for processing a substrate, and

FIG. 6A and FIG. 6B illustrate the temperature dependency of the etch rates of two different silicon-containing materials and the etch rates of two different modified silicon-containing materials, respectively, when etched using a halogen-containing gaseous reactant.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

The illustrations presented herein are not meant to be actual views of any particular material, structure, or device, but are merely idealized representations that are used to describe embodiments of the disclosure.

### DETAILED DESCRIPTION

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

Throughout this disclosure, a “process” may refer to a series of one or more steps leading to an end result. Further, a “step” may refer to a measure taken in order to achieve one or more pre-defined end results. Generally, a process may be a single-step or a multistep process. Additionally, a process may be divisible to a plurality of sub-processes, wherein individual sub-processes of such plurality of sub-processes may or may not share common steps.

In this specification, the term “unit” may refer to a device suitable for or configured to execute at least one specific process. A unit may typically comprise one or more constituents, each of which can be categorized as a component that is part of the said unit. Generally, a unit may comprise any components that are essential and/or advantageous for executing the specific process(es) for which the unit is suitable or configured. These components could encompass, for example, mechanical, electrical, optical, pneumatic, and/or hydraulic elements.

Further, “etching” may refer to removing material from a substrate. Additionally or alternatively, etching may refer to forming volatile species, for example, via one or more chemical reactions. As such, an “etch process” may refer to a process suitable, adapted, or configured for etching. In some embodiments, an etch process may be implemented as a thermal or active-species-enhanced etch process, as a cyclic etch process, and/or as a self-limiting etch process.

On the one hand, a “thermal” etch process may refer to an etch process, wherein etching is not purposefully and/or substantially driven by active species or energy derived therefrom. Additionally or alternatively, a thermal etch process may refer to an etch process, wherein reactants other than active species are used. On the other hand, an “active-species-enhanced etch process” may refer to an etch process, wherein etching is purposefully and/or substantially driven by active species and/or energy derived therefrom. Additionally or alternatively, an active-species-enhanced etch process may refer to an etch process, wherein at least one active species is used as a reactant.

Throughout this specification, a “cyclic” etch process may refer to an etch process comprising two or more sub-processes, wherein any at least two of the two or more sub-processes or each of the two or more sub-processes is repeated at least once in a cyclical manner.

Further, a “self-limiting” etch process may refer to an etch process, wherein at least one sub-process exhibits self-limiting characteristics. Such self-limiting characteristics may refer to the reaction rate of the at least one sub-process decreasing rapidly or tending to a negligeable reaction rate with increasing process time. Additionally or alternatively, a self-limiting etch process may refer to an etch process, wherein at least part of a surface of a substrate is chemically modified to form a modified surface layer defined by a sharp chemical composition gradient and/or a distinguishing physical structure.

Throughout this disclosure, a “layer” or “film” may refer to a structure having a certain thickness formed on a surface. A layer may be continuous or discontinuous. A film or layer may or may not be constituted by a discrete single film or layer having certain characteristics or multiple films or layers. A boundary between adjacent films or layers may or may not be clear and may or may not be established based on physical, chemical, and/or any other characteristics, formation processes or sequences, and/or functions or purposes of the adjacent films or layers. A layer or film may or may not comprise pinholes. A layer of film may or may not be porous.

In this disclosure, a “substrate” may refer to any underlying material or materials that may be used to form, or upon which, a device, a circuit, or a film may be formed. A substrate may, for example, include one or more bulk materials, such as silicon (e.g., monocrystalline silicon); other Group IV materials, e.g., germanium; and/or compound semiconductor materials, such as gallium arsenide. A substrate may or may not comprise one or more layers overlying or underlying a bulk material. Additionally or alternatively, a substrate may comprise various structures, such as recesses, vias, lines, and the like formed within or on at least a portion of a layer of the substrate.

Throughout this specification, a “control unit” may refer to a device, potentially an electronic device, possessing at least one designated function associated with determining and/or influencing an operational condition, state, or parameter pertaining to another device, unit, or component. A control unit may or may form an integral part of the multifunction control system. Further, a control unit being “configured” to execute a process may refer to the control unit being capable and appropriate for the process. This can be realized in a variety of ways. For instance, the control unit may comprise at least one processor and at least one memory connected to the said processor. The memory may store program code instructions that, upon execution on the processor, prompt the processor to undertake the procedure in question. Memory devices within a control unit may comprise non-transitory computer-readable media, such as physical computer storage including hard drives, solid-state memory, random access memory (RAM), read-only memory (ROM), optical disc, volatile or non-volatile storage, combinations thereof, and the like. Additionally or alternatively, any functionally described attributes of a control unit may be executed, at least partially, by one or more hardware logic components. For example, and without limitation, illustrative types of appropriate hardware logic components include Field Programmable Gate Arrays (FPGAs), Application Specific Integrated Circuits (ASICs), Application Specific Standard Products (ASSPs), System on a Chips (SOCs), Complex Programmable Logic Devices (CPLDs), and so the like. A control unit may generally function according to any suitable principles and via any suitable circuitry and/or signals recognized in the art.

In this specification, a “semiconductor manufacturing pre-cleaning method” may refer to a method for pre-cleaning a semiconductor substrate prior to a subsequent semiconductor manufacturing process. Additionally or alternatively, a semiconductor manufacturing pre-cleaning method may refer to a method for etching a substrate to enhance or facilitate the running of a subsequent semiconductor manufacturing process. Additionally or alternatively, a semiconductor manufacturing pre-cleaning method may refer to a method for etching a substrate for controlling the chemical composition of a surface of a substrate.

Throughout this specification, a “species” may refer to a chemical species, such as a chemical compound or a molecular structural unit of a solid array, or a molecular entity. Additionally or alternatively, species may refer to one or more structurally distinct atoms, molecules, ions, radicals, or complexes. Herein, an “ion” may refer to an atomic or molecular particle possessing a net electric charge, and/or a “radical” may refer to an atomic or molecular particle possessing an unpaired electron. Further, “active species” may refer to unstable species formed in plasma, via interactions with catalytic material(s) at elevated temperatures, and/or by other suitable means. Additionally or alternatively, active species may refer to ions and/or radicals.

In this disclosure, a “reactant” or “precursor” may refer to a species suitable for or configured to participate in a chemical reaction producing another species. Further, a “gaseous” reactant or precursor may refer to a reactant or precursor in gas-like form, e.g., as a gas, a vapor, or a plasma.

In this specification, a “process chamber” may refer to a chamber suitable for or configured to enable performing a process on a substrate. Additionally or alternatively, a process chamber may refer to a vacuum chamber within which a process may be performed. A process chamber may comprise one or more process stations. Herein, a “process station” may refer to a location suitable for or configured to hold a substrate so that a process may be performed on the substrate. Additionally or alternatively, a process station may refer to a portion of a process chamber. In some embodiments, individual process stations of a process chamber may be arranged in gas isolation from each other or configured to be in gas isolation from each other while one or more substrates are processed inside one or more of the individual process stations. In such embodiments, individual process stations of a process chamber may be arranged in gas isolation by way of physical barriers, and/or gas bearings, and/or gas curtains.

In some embodiments, the presently described methods, devices, and apparatuses may be useful in the fields of microfabrication and nanofabrication. In some embodiments, the presently described methods, devices, and apparatuses may be useful in the fields of microelectromechanical systems, microsystems, photonics, photovoltaics, display devices, and/or semiconductor manufacturing technology. In some embodiments, the presently described methods, devices, and apparatuses may be useful for etching substrates comprising silicon-containing materials. In some embodiments, the presently described methods, devices, and apparatuses may be useful for semiconductor processing pre-cleaning, for example, prior to forming an epitaxial layer. In some embodiments, the presently described methods, devices, and apparatuses may be useful for forming epitaxial layers, for example, with reduced thermal budgets. In some embodiments, the presently described methods, devices, and apparatuses may be useful for forming active regions in semiconductor devices, such as transistors. In some embodiments, the presently described methods, devices, and apparatuses may be useful for forming source regions or drain regions of metal-oxide-semiconductor field-effect transistors (MOSFETs). In some embodiments, the presently described methods, devices, and apparatuses may be useful for forming epitaxial phosphorus-doped silicon layers and/or epitaxial boron-doped silicon-germanium layers. In some embodiments, the presently described methods, devices, and apparatuses may be useful for tuning active region geometries in semiconductor devices, such as semiconductor transistors. In some embodiments, the presently described methods, devices, and apparatuses may be useful for tuning the nanosheet dimensions of nanosheet transistors.

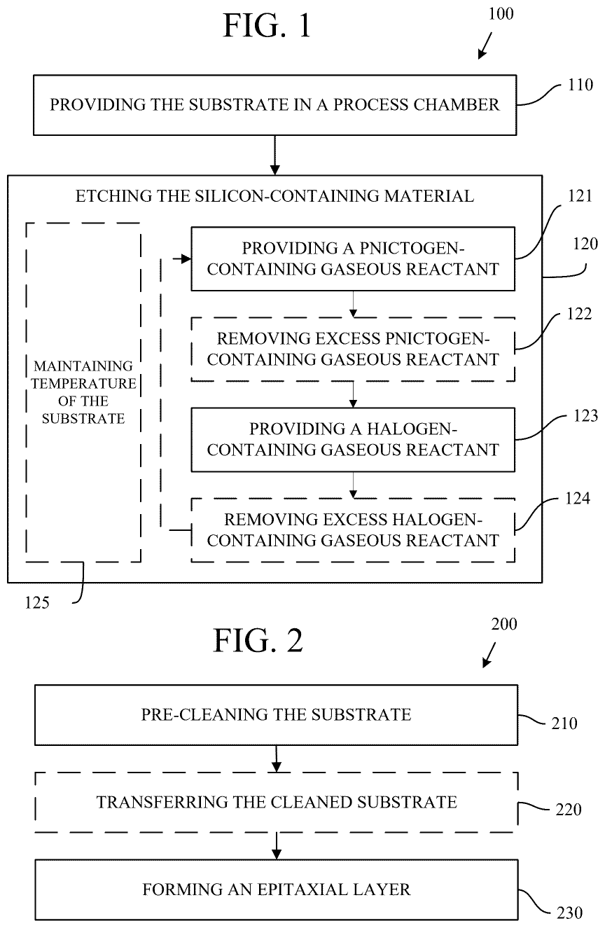

FIG. 1 schematically illustrates a method 100 for etching a substrate according to an embodiment. Unless explicitly stated otherwise, the method 100 of the embodiment of FIG. 1 may or may not comprise any feature(s) disclosed within this specification, mutatis mutandis. Other embodiments may or may not be identical or similar to the embodiment of FIG. 1.

The method 100 of the embodiment of FIG. 1 may be specifically implemented as a semiconductor manufacturing pre-cleaning method. In other embodiments, a method for etching a substrate may be implemented in any suitable manner, for example, as a semiconductor manufacturing pre-cleaning method.

The method 100 of the embodiment of FIG. 1 comprises providing the substrate in a process chamber 110, wherein the substrate comprises a silicon-containing material. The method 100 also comprises etching the silicon-containing material 120 at least partly, i.e., partly or completely.

The process of etching the silicon-containing material 120 of the embodiment of FIG. 1 comprises providing a pnictogen-containing gaseous reactant 121 in the process chamber such that the silicon-containing material is exposed to the pnictogen-containing gaseous reactant to form a modified silicon-containing material. The process of etching the silicon-containing material 120 also comprises providing a halogen-containing gaseous reactant 123 in the process chamber such that the modified silicon-containing material is exposed to the halogen-containing gaseous reactant to at least partly etch the modified silicon-containing material. In some embodiments, such a process of etching the silicon-containing material may enable etching a silicon-containing material with high precision, high selectivity, and/or limited thermal budget.

In the embodiment of FIG. 1, the silicon-containing material may comprise at least one silicon-oxygen compound, such as silica and/or one or more silicate compounds. In some embodiments, a silicon-containing material comprising at least one silicon-oxygen compound may enable etching with increased etch rates and/or reduce the need for further etch treatments to reduce the number of deposits and/or etch residues remaining on a substrate. In other embodiments, a silicon-containing material may or may not comprise at least one silicon- oxygen compound.

Additionally of alternatively, the silicon-containing material of the embodiment of FIG. 1 may comprise elemental silicon, such as monocrystalline silicon, polycrystalline silicon, and/or amorphous silicon. In some embodiments, a silicon-containing material comprising elemental silicon, such as monocrystalline silicon, polycrystalline silicon, and/or amorphous silicon, may enable etching with increased etch rates and/or facilitate implementing a process of etching the silicon-containing material as a self-limiting etch process. In other embodiments, a silicon-containing material may or may not comprise elemental silicon.

In the embodiment of FIG. 1, the pnictogen-containing gaseous reactant may comprise an inorganic pnictogen species, such as an inorganic pnictogen compound, e.g., a pnictogen chloride or a pnictogen hydride. Examples of such inorganic pnictogen compounds include nitrogen trichloride, ammonia, phosphorus trichloride, phosphorus pentachloride, phosphine, arsenic trichloride, and arsine. In some embodiments, a pnictogen-containing gaseous reactant comprising an inorganic pnictogen species may facilitate reducing carbon contamination of a substrate. In other embodiments, a pnictogen-containing gaseous reactant may or may not comprise an inorganic pnictogen species. For example, in some embodiments, a pnictogen-containing gaseous reactant may comprise an organic pnictogen-containing compound, such as tris(trimethylsilyl)phosphine or tris(trimethylsilyl)arsine. In some embodiments, a pnictogen-containing gaseous reactant may comprise pnictogen-containing active species.

In the embodiment of FIG. 1, the pnictogen-containing gaseous reactant may comprise phosphorus and/or arsenic. In some embodiments, a pnictogen-containing gaseous reactant comprising phosphorus and/or arsenic may facilitate etching a silicon-containing material with increased selectivity and/or at reduced temperatures. In other embodiments, a pnictogen-containing gaseous reactant may or may not comprise phosphorus and/or arsenic. For example, in some embodiments, a pnictogen-containing gaseous reactant may comprise antimony or bismuth. In some embodiments, a pnictogen-containing gaseous reactant may comprise a pnictogen other than nitrogen. In some embodiments, a pnictogen-containing gaseous reactant may comprise nitrogen.

The halogen-containing gaseous reactant of the embodiment of FIG. 1 may comprise a chlorine-containing species, such as a chlorine-containing compound, e.g., chlorine or carbon tetrachloride. In some embodiments, a halogen-containing gaseous reactant comprising a chlorine-containing species may facilitate etching a silicon-containing material with increased selectivity and/or at reduced temperatures. In other embodiments, a halogen-containing gaseous reactant may or may not comprise a chlorine-containing species. For example, in some embodiments, a halogen-containing gaseous reactant may comprise a fluorine-containing species or a bromine-containing species. In some embodiments, a halogen-containing gaseous reactant may comprise halogen-containing active species.

In the embodiment of FIG. 1, etching the silicon-containing material 120 may be implemented as a thermal etch process. In some embodiments, a process of etching the silicon-containing material being implemented as a thermal etch process may facilitate etching a silicon-containing material with increased etch rate uniformity across a substrate, for example, in case said substrate comprises high-aspect-ratio structures and/or laterally extending recesses. In other embodiments, a process of etching the silicon-containing material may or may not be implemented as a thermal etch process. For example, in some embodiments, a process of etching the silicon-containing material may be implemented as an active-species-enhanced etch process. In such embodiments, said process of etching the silicon-containing material may comprise one or more sub-processes, wherein a substrate is exposed to active species to drive the etch process.

As indicated in FIG. 1 using a dashed boundary, the process of etching the silicon- containing material 120 of the embodiment of FIG. 1 may comprise maintaining temperature of the substrate 125 less than or equal to 600° C., or to 550° C., or to 500° C., or to 450° C. and/or greater than or equal to 50° C., or to 100° C., or to 150° C., or to 200° C., or to 250° C.° C., or to 300° C., or to 350° C. In embodiments, wherein a process of etching the silicon-containing material may comprises maintaining temperature of the substrate in such temperatures, the substrate may be maintained at such temperatures during or throughout one or more, e.g., each, sub-process of the process of etching the silicon-containing material. In some embodiments, a process of etching the silicon-containing material comprising maintaining temperature of the substrate within such temperatures may enable reducing degradation of substrate properties due to thermal diffusion and/or thermal stresses. Additionally or alternatively, a process of etching the silicon-containing material comprising maintaining temperature of the substrate within such temperatures may reduce processing temperature differences between a method for etching a substrate and a subsequent semiconductor manufacturing process, such as epitaxial growth, which may in turn improve throughput and/or facilitate reducing power consumption during processing of said substrate. In other embodiments, a process of etching the silicon-containing material may or may not comprise maintaining temperature of the substrate within such temperatures. For example, in some embodiments, a process of etching the silicon-containing material may comprise maintaining temperature of the substrate below 50° C. or above 600° C.

As indicated in FIG. 1 using dashed boundaries, the process of etching the silicon-containing material 120 of the embodiment of FIG. 1 may further comprise removing excess pnictogen-containing gaseous reactant 122 from the process chamber prior to providing a halogen-containing gaseous reactant 123 and/or removing excess halogen-containing gaseous reactant 124 from the process chamber after providing a halogen-containing gaseous reactant 123. In embodiments, wherein a process of etching the silicon-containing material comprises removing excess pnictogen-containing gaseous reactant and/or removing excess halogen-containing gaseous reactant, the removal of excess pnictogen-containing gaseous reactant and/or halogen-containing gaseous reactant may be implemented using process chamber purging steps prior to and/or after providing a halogen-containing gaseous reactant, respectively. In some embodiments, a process of etching the silicon-containing material comprising removing excess pnictogen-containing gaseous reactant and/or removing excess halogen-containing gaseous reactant may facilitate achieving more accurate etch depth control and/or enable safe utilization of incompatible pnictogen-containing gaseous reactant and halogen-containing gaseous reactant combinations.

In other embodiments, a process of etching the silicon-containing material may or may not comprise removing excess pnictogen-containing gaseous reactant and/or removing excess halogen-containing gaseous reactant. For example, in some embodiments, processes of providing a pnictogen-containing gaseous reactant and providing a halogen-containing gaseous reactant may at least partly temporally overlap or coincide. In some such embodiments, compatible pnictogen-containing gaseous reactant and halogen-containing gaseous reactant combinations may be utilized and/or the pnictogen-containing gaseous reactant and the halogen-containing gaseous reactant may be maintained spatially separated in a process chamber. As such, the processes of providing a pnictogen-containing gaseous reactant 121 and providing a halogen-containing gaseous reactant 123 may alternatively at least partly temporally overlap.

As depicted schematically in FIG. 1 using a dashed arrow extending from the process of removing excess halogen-containing gaseous reactant 124 to the process of providing a pnictogen-containing gaseous reactant 121, the process of etching the silicon-containing material 120 of the embodiment of FIG. 1 may be implemented as a cyclic etch process. In some embodiments, a process of etching the silicon-containing material being implemented as a cyclic etch process may facilitate achieving more accurate etch depth control and/or higher total etch depth. In other embodiments, a process of etching the silicon-containing material may or may not be implemented as a cyclic etch process.

In some embodiments, wherein a process of etching the silicon-containing material is implemented as a cyclic etch process, (sub-)processes of providing a pnictogen-containing gaseous reactant and providing a halogen-containing gaseous reactant may be repeated at least once in a cyclical manner. In some embodiments, wherein a process of etching the silicon-containing material is implemented as a cyclic etch process, (sub-)processes of providing a pnictogen-containing gaseous reactant, removing excess pnictogen-containing gaseous reactant, and providing a halogen-containing gaseous reactant may be repeated at least once in a cyclical manner. In some embodiments, wherein a process of etching the silicon-containing material is implemented as a cyclic etch process, (sub-)processes of providing a pnictogen-containing gaseous reactant, providing a halogen-containing gaseous reactant, and removing excess halogen-containing gaseous reactant may be repeated at least once in a cyclical manner. In some embodiments, wherein a process of etching the silicon-containing material is implemented as a cyclic etch process, (sub-)processes of providing a pnictogen-containing gaseous reactant, removing excess pnictogen-containing gaseous reactant, providing a halogen-containing gaseous reactant, and removing excess halogen-containing gaseous reactant may be repeated at least once in a cyclical manner. In some embodiments, wherein a process of etching the silicon-containing material is implemented as a cyclic etch process and comprises providing a pnictogen-containing gaseous reactant, removing excess pnictogen-containing gaseous reactant, providing a halogen-containing gaseous reactant, and/or removing excess halogen-containing gaseous reactant as well as one or more additional sub-processes, the additional sub-processes may be repeated cyclically in similar manner.

In the embodiment of FIG. 1, the process of etching the silicon-containing material 120 may be implemented as a self-limiting etch process. Without the presently disclosed subject matter being bound by any particular theory or mode of operation, in some embodiments, wherein a process of etching the silicon-containing material is implemented as a self-limiting etch process, the self-limiting characteristic of the etch process may be associated with the limited depth to which a pnictogen originating from a pnictogen-containing gaseous reactant diffuses within a silicon-containing material and/or with etch selectivity between a silicon-containing material and a modified silicon-containing material under exposure to a halogen-containing gaseous reactant, for example, within a certain temperature range. In other embodiments, a process of etching the silicon-containing material may or may not be implemented as a self-limiting etch process.

FIG. 2 schematically illustrates a method 200 for processing a substrate according to an embodiment. Unless explicitly stated otherwise, the method 200 of the embodiment of FIG. 2 may or may not comprise any feature(s) disclosed within this specification, mutatis mutandis. Other embodiments may or may not be identical or similar to the embodiment of FIG. 2.

In the embodiment of FIG. 2, the method 200 comprises pre-cleaning the substrate 210 in a process chamber using a method for etching a substrate according to the first aspect to form a cleaned substrate and forming an epitaxial layer 230 on the cleaned substrate. In some embodiments, forming an epitaxial layer on a cleaned substrate formed using a method for etching a substrate according to the first aspect may enable forming an epitaxial layer with higher epitaxial layer quality and/or with a reduced thermal budget.

The process of pre-cleaning the substrate 210 of the embodiment of FIG. 2 may be performed in the process chamber, whereas the process forming an epitaxial layer 230 of the embodiment of FIG. 2 may be performed in an epitaxial deposition reactor separate from the process chamber. In such case, the method 200 may further comprise transferring the cleaned substrate 220 from the process chamber to the epitaxial deposition reactor without breaking vacuum. In some embodiments, wherein processes of pre-cleaning the substrate and forming an epitaxial layer are performed in the process chamber and an epitaxial deposition reactor separate from the process chamber, respectively, transferring the cleaned substrate from the process chamber to the epitaxial deposition reactor without breaking vacuum may facilitate maintaining the cleaned substrate in pristine condition for forming an epitaxial layer, which may in turn enable forming an epitaxial layer with higher epitaxial layer quality. In other embodiments, processes of pre-cleaning the substrate and forming an epitaxial layer of a method for processing a substrate may or may not be performed in a process chamber and an epitaxial deposition reactor separate from the process chamber, respectively. In other embodiments, wherein processes of pre-cleaning the substrate and forming an epitaxial layer of a method for processing a substrate are performed in a process chamber and an epitaxial deposition reactor separate from the process chamber, respectively, the method may or may not comprise transferring the cleaned substrate from the process chamber to the epitaxial deposition reactor without breaking vacuum. For example, in some embodiments, a process of forming an epitaxial layer may be optimized for forming an epitaxial layer on cleaned substrates with higher levels of contamination.

Alternatively, both the process of pre-cleaning the substrate 210 and the process of forming an epitaxial layer 230 may be performed in the same process chamber. In some embodiments, both pre-cleaning the substrate and forming an epitaxial layer being performed in the same process chamber may facilitate maintaining the cleaned substrate in pristine condition for forming an epitaxial layer, which may in turn enable forming an epitaxial layer with higher epitaxial layer quality. In other embodiments, processes of pre-cleaning the substrate and forming an epitaxial layer may or may not be performed in the same process chamber.

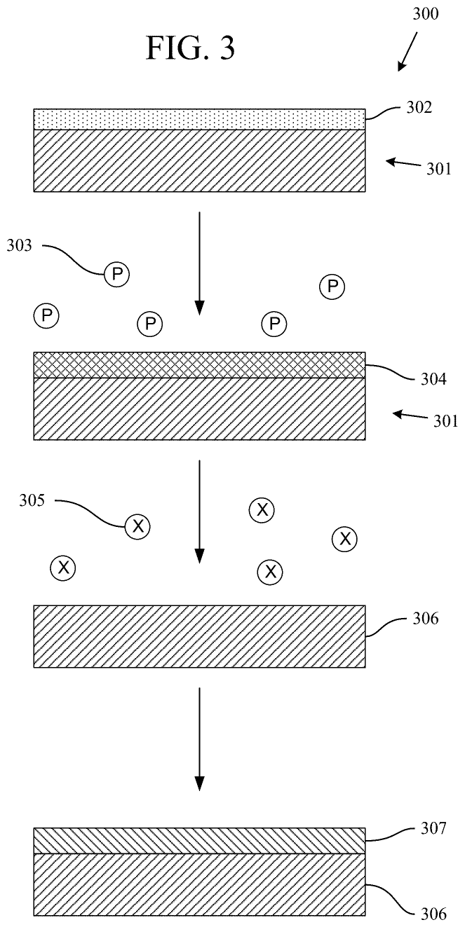

FIG. 3 schematically illustrates a series of stages of a method for processing a substrate according to an embodiment. The method 300 of the embodiment of FIG. 3 comprises pre-cleaning a substrate 301, such as a patterned silicon substrate, comprising a silicon-containing material 302, such as silica, according to the first aspect to form a cleaned substrate 306 and forming an epitaxial layer 307, such as an phosphorous-doped silicon layer or boron-doped silicon-germanium layer, on the cleaned substrate 306. Unless explicitly stated otherwise, the method 300 of the embodiment of FIG. 3 may or may not comprise any feature(s) disclosed within this specification, mutatis mutandis. Other embodiments may or may not be identical or similar to the embodiment of FIG. 3.

As illustrated in the topmost part of FIG. 3, the method 300 is initiated by providing the substrate 301 in the process chamber. Then, as depicted schematically in the second and third parts of FIG. 3, the method 300 continues by providing a pnictogen-containing gaseous reactant 303, such as phosphine, in the process chamber such that the silicon-containing material 302 is exposed to the pnictogen-containing gaseous reactant 303 to form a modified silicon-containing material 304. Following the provision of the pnictogen-containing gaseous reactant 303 in the process chamber, a halogen-containing gaseous reactant 305, such as chlorine, is provided in the process chamber such that the modified silicon-containing material 304 is exposed to the halogen-containing gaseous reactant 305 to etch the modified silicon-containing material 304, which results in the formation of the cleaned substrate 306. Finally, as depicted in the bottommost part of FIG. 3, the method 300 concludes by forming epitaxial layer 307 on the cleaned substrate 306.

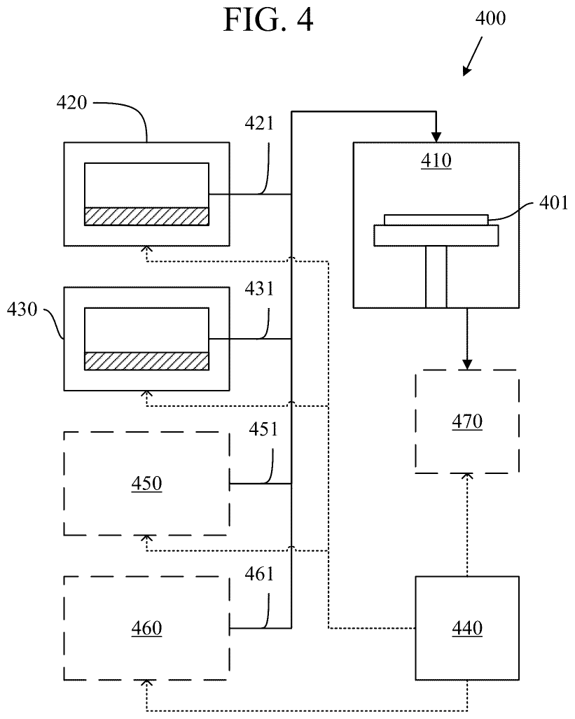

FIG. 4 schematically depicts a device 400 for etching a substrate 401 according to an embodiment. Unless explicitly stated otherwise, the device 400 of the embodiment of FIG. 4 may or may not comprise any feature(s) disclosed within this specification, mutatis mutandis. Other embodiments may or may not be identical or similar to the embodiment of FIG. 4.

In the embodiment of FIG. 4, the device 400 comprises a process chamber 410 for holding the substrate 401, a first reactant supply unit 420 for providing a pnictogen-containing gaseous reactant 421 in the process chamber 410, a second reactant supply unit 430 for providing a halogen-containing gaseous reactant 431 in the process chamber 410, and a control unit 440 configured to control at least the first reactant supply unit 420 and the second reactant supply unit 430 to etch the substrate 401 in accordance with a method for etching a substrate according to the first aspect.

As indicated in FIG. 4 using a dashed boundary, the device 400 of the embodiment of FIG. 4 may also comprise a purge gas supply unit 450 for providing a purge gas 451 into the process chamber 410. As indicated using a dotted arrow extending from the control unit 440 to the purge gas supply unit 450, the control unit 440 may then be configured to further control at least the purge gas supply unit 450 for removing the excess pnictogen-containing gaseous reactant 421 and/or the excess halogen-containing gaseous reactant 431 from the process chamber 410. In other embodiments, a device for etching a substrate may or may not comprise such a purge gas supply unit.

As again indicated in FIG. 4 using a dashed boundary, the device 400 of the embodiment of FIG. 4 may further comprise an epitaxial precursor supply unit 460 for providing one or more precursors 461 into the process chamber 410. As indicated using a dotted arrow extending from the control unit 440 to the epitaxial precursor supply unit 460, the control unit 440 may then be configured to further control at least the epitaxial precursor supply unit 460 for forming an epitaxial layer on the substrate 401 in the process chamber 410. In other embodiments, a device for etching a substrate may or may not comprise such an epitaxial precursor supply unit.

The device 400 of the embodiment of FIG. 4 may further comprise an exhaust unit 470 for facilitating the removal of fluid(s) and/or fluid-like substance(s) from the process chamber 410 and/or for maintaining pressure within the process chamber 410 at a pre-determined pressure range. As indicated using a dotted arrow extending from the control unit 440 to the exhaust unit 470, the control unit 440 may then be configured to further control at least the exhaust unit 470 for facilitating the removal of fluid(s) and/or fluid-like substance(s), e.g., reactant(s), reaction by-product(s), and/or precursor(s), from the process chamber 410 and/or for maintaining pressure within the process chamber 410 at a pre-determined pressure range, e.g., at reduced pressures or at sub-atmospheric pressures. In other embodiments, a device for etching a substrate may or may not comprise such an exhaust unit 470.

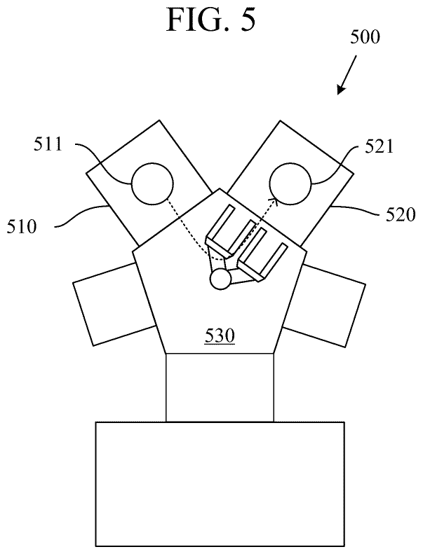

FIG. 5 schematically depicts an apparatus 500 for processing a substrate 511 according to an embodiment. Unless explicitly stated otherwise, the apparatus 500 of the embodiment of FIG. 5 may or may not comprise any feature(s) disclosed within this specification, mutatis mutandis. Other embodiments may or may not be identical or similar to the embodiment of FIG. 5. For example, the apparatus 500 of the embodiment of FIG. 5 is implemented as a modular semiconductor manufacturing platform apparatus. In other embodiments, an apparatus for processing a substrate may be implemented in any suitable manner and may or may not be implemented as a modular semiconductor manufacturing platform apparatus.

In the embodiment of FIG. 5, the apparatus 500 comprises a device 510 in accordance with the third aspect for pre-cleaning the substrate 511 to form a cleaned substrate 521 and an epitaxial deposition reactor 520. As indicated schematically in FIG. 5 using a dotted arrow extending from the device 510 to the epitaxial deposition reactor 520, the epitaxial deposition reactor 520 is coupled to the device 510 such that the cleaned substrate 521 may be transferred from the device 510 to the epitaxial deposition reactor without breaking vacuum.

In particular, the apparatus 500 comprises a wafer-handling chamber 530 connected to the device 510 and to the epitaxial deposition reactor 520, whereby the epitaxial deposition reactor 520 is indirectly coupled to the device 510 via the wafer-handling chamber 530. In other embodiments, wherein an epitaxial deposition reactor is coupled to a device for etching a substrate such that the cleaned substrate may be transferred from the device to the epitaxial deposition reactor without breaking vacuum, the epitaxial deposition reactor 520 may be coupled to the device in any suitable manner, for example, directly or indirectly via one or more additional components, e.g., a wafer-handling chamber, a load lock, or the like.

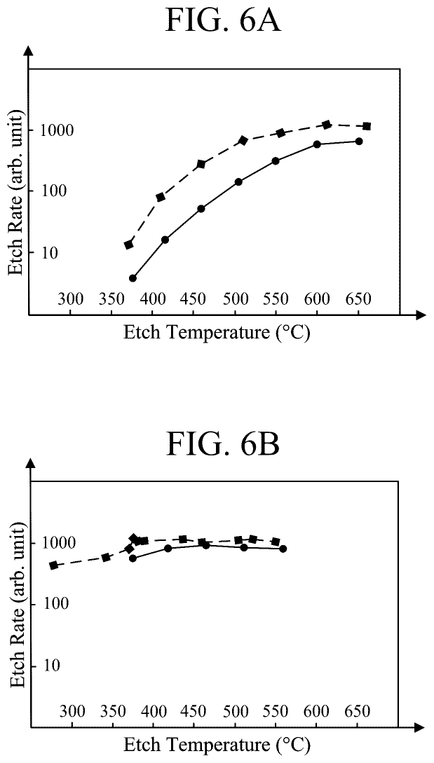

FIG. 6A illustrates the temperature dependency of the etch rates of two different silicon-containing materials when etched using a halogen-containing gaseous reactant, namely chlorine. In FIG. 6A, results relating to silica as the silicon-containing material are depicted using a dashed line provided with square datapoints, whereas results relating to intrinsic monocrystalline silicon as the silicon-containing material are depicted using a solid line provided with circular datapoints. As shown in FIG. 6A, silica exhibits considerably higher etch rates than intrinsic monocrystalline silicon throughout the temperature range extending from approximately 370° C. to approximately 660° C., and the etch rates of both silica and intrinsic monocrystalline silicon decrease considerably with decreasing etch temperature.

FIG. 6B illustrates the temperature dependency of the etch rates of two different modified silicon-containing materials when etched using the same halogen-containing gaseous reactant as in the case of FIG. 6A above. In FIG. 6B, results relating to phosphorus-doped silica as the modified silicon-containing material are depicted using a dashed line provided with square datapoints, whereas results relating to highly phosphorus-doped monocrystalline silicon as the modified silicon-containing material are depicted using a solid line provided with circular datapoints. As shown in FIG. 6B, the etch rates of both phosphorus-doped silica and highly phosphorus-doped monocrystalline silicon exhibit only modest temperature dependency, and the etch rates of both phosphorus-doped silica and highly phosphorus-doped monocrystalline silicon are considerably higher than those of silica and intrinsic monocrystalline silicon at lower temperatures.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for etching a substrate, the method comprising:
providing the substrate in a process chamber, the substrate comprising a silicon- containing material; and
etching the silicon-containing material at least partly, wherein etching the silicon- containing material comprises:
providing a pnictogen-containing gaseous reactant in the process chamber such that the silicon-containing material is exposed to the pnictogen-containing gaseous reactant to form a modified silicon-containing material, and
providing a halogen-containing gaseous reactant in the process chamber such that the modified silicon-containing material is exposed to the halogen-containing gaseous reactant to at least partly etch the modified silicon-containing material.

2. A method according to claim 1, wherein the silicon-containing material comprises at least one silicon-oxygen compound including at least one of silica or one or more silicate compounds.

3. A method according to claim 1, wherein the silicon-containing material comprises elemental silicon including at least one of monocrystalline silicon, polycrystalline silicon, or amorphous silicon.

4. A method according to claim 1, wherein the pnictogen-containing gaseous reactant comprises an inorganic pnictogen species including an inorganic pnictogen compound comprising a pnictogen chloride or a pnictogen hydride.

5. A method according to claim 1, wherein the pnictogen-containing gaseous reactant comprises at least one of phosphorus or arsenic.

6. A method according to claim 1, wherein the halogen-containing gaseous reactant comprises a chlorine-containing species including a chlorine-containing compound comprising chlorine or carbon tetrachloride.

7. A method according to claim 1, wherein etching the silicon-containing material is implemented as a thermal etch process.

8. A method according to claim 1, wherein etching the silicon-containing material comprises maintaining temperature of the substrate at one or more of:
less than or equal to 600° C., 550° C., 500° C., or 450° C.; or
greater than or equal to 50° C., 100° C., 150° C., 200° C., 250° C., 300° C., or 350° C.

9. A method according to claim 1, wherein etching the silicon-containing material comprises at least one of removing excess pnictogen-containing gaseous reactant from the process chamber prior to providing a halogen-containing gaseous reactant or removing excess halogen- containing gaseous reactant from the process chamber after providing a halogen-containing gaseous reactant.

10. A method according to claim 1, wherein providing a pnictogen-containing gaseous reactant and providing a halogen-containing gaseous reactant at least partly temporally overlap.

11. A method according to claim 1, wherein etching the silicon-containing material is implemented as a cyclic etch process.

12. A method according to claim 1, wherein etching the silicon-containing material is implemented as a self-limiting etch process.

13. A method according to claim 1, implemented as a semiconductor manufacturing pre- cleaning method.

14. A method for processing a substrate, the method comprising pre-cleaning the substrate in a process chamber using a method in accordance with claim 1 to form a cleaned substrate and forming an epitaxial layer on the cleaned substrate.

15. A method according to claim 14, wherein pre-cleaning the substrate and forming an epitaxial layer are performed in the process chamber and an epitaxial deposition reactor separate from the process chamber, respectively, and the method comprises transferring the cleaned substrate from the process chamber to the epitaxial deposition reactor without breaking vacuum.

16. A method according to claim 14, wherein both pre-cleaning the substrate and forming an epitaxial layer are performed in the process chamber.

17. A device for etching a substrate, the device comprising:
a process chamber for holding the substrate,
a first reactant supply unit for providing a pnictogen-containing gaseous reactant in the process chamber,
a second reactant supply unit for providing a halogen-containing gaseous reactant in the process chamber, and
a control unit configured to control at least the first reactant supply unit and the second reactant supply unit to conduct a method in accordance with claim 1.

18. A device according to claim 17, wherein the device comprises a purge gas supply unit for providing a purge gas in the process chamber.

19. A device according to claim 17, wherein the device comprises an epitaxial precursor supply unit for providing one or more precursors in the process chamber.

20. An apparatus for processing a substrate, the apparatus comprising:
a device in accordance with claim 17 for pre-cleaning the substrate to form a cleaned substrate, and
an epitaxial deposition reactor coupled to the device for transferring the cleaned substrate from the device to the epitaxial deposition reactor without breaking vacuum.
